(19) United States
(12) Patent Application Publication
(10) Pub. No.: US 2023/0343493 A1
(43) Pub. Date: Oct. 26, 2023

(54) MULTI-LAYER ELECTRICAL DEVICE

(71) Applicant: Bourns, Inc., Riverside, CA (US)

(72) Inventors: Che-Yi SU, New Taipei City (TW); Jeff CHIEN, New Taipei City (TW); Stelar CHU, New Taipei City (TW); Simon CHUNG, New Taipei City (TW)

(21) Appl. No.: 18/346,823

(22) Filed: Jul. 4, 2023

Related U.S. Application Data
(63) Continuation of application No. PCT/US2022/011249, filed on Jan. 5, 2022.
(60) Provisional application No. 63/134,316, filed on Jan. 6, 2021.

(51) Int. Cl. H01C 1/144; H01C 7/02; H01C 7/18; H01C 1/14

(52) U.S. Cl. CPC H01C 1/144; H01C 7/021; H01C 7/18; H01C 1/1406

(57) ABSTRACT

In some embodiments, a multi-layer electrical device can include multiple electrodes connected to respective terminals, with at least two selected terminals being configured to allow movement relative to each other to accommodate a change in separation distance of the respective electrodes resulting from a change in temperature, and to allow a solder to provide a connection therebetween when the multi-layer electrical device is soldered on a mounting surface. In some embodiments, the multi-layer electrical device can further include a layer having a temperature-dependent electrical property implemented between each neighboring pair of electrodes.

### CROSS-REFERENCE TO RELATED APPLICATION(S)

This application is a continuation of International Application No. PCT/US2022/011249 filed Jan. 5, 2022, entitled MULTI-LAYER ELECTRICAL DEVICE, which claims priority to U.S. Provisional Application No. 63/134,316 filed Jan. 6, 2021, entitled MULTI-LAYER ELECTRICAL DEVICE, the benefits of the filing dates of which are hereby claimed and the disclosures of which are hereby expressly incorporated by reference herein in their entirety.

### BACKGROUND

### Field

The present disclosure relates to surface mountable multi-layer electrical devices.

### Description of the Related Art

Many electronic devices are configured to be mounted to a surface of a circuit board. Such devices are commonly referred to as surface-mount devices (SMDs) or surface-mount technology (SMT) devices.

Some SMDs or SMT devices are implemented as a multi-layer electrical device that includes a plurality of layers with each layer being formed from a material having an electrical property. Each of such a plurality of layers can implemented between respective layers such that the multi-layer electrical layer provides a desired electrical functionality.

### SUMMARY

In some implementations, the present disclosure relates to a multi-layer electrical device that includes multiple electrodes connected to respective terminals, with at least two selected terminals configured to allow movement relative to each other to accommodate a change in separation distance of the respective electrodes resulting from a change in temperature, and to allow a solder to provide a connection therebetween when the multi-layer electrical device is soldered on a mounting surface.

In some embodiments, the multi-layer electrical device can further include a temperature-dependent layer implemented between each neighboring pair of electrodes. The temperature-dependent layer can include a material having a temperature-dependent electrical property. The temperature-dependent layer can result in the change in separation distance of the respective neighboring pair of electrodes with the change in temperature. The material having the temperature-dependent electrical property can be configured such that the separation distance of the respective neighboring pair of electrodes increases with an increase in temperature.

In some embodiments, the multiple electrodes can include first, second and third electrodes connected to respective first, second and third terminals, such that a first temperature-dependent layer is between the first and second electrodes, and a second temperature-dependent layer is between the second and third electrodes, with the first electrode being closest to the mounting surface when the multi-layer electrical device is mounted thereon. The at least two selected terminals can include the first terminal and the third terminal. The first and third terminals can be implemented on a first side of the multi-layer electrical device, and the second terminal can be implemented on a second side of the multi-layer electrical device. The first and second sides of the multi-layer electrical device can be on opposing sides of the multi-layer electrical device.

In some embodiments, each of the first and second temperature-dependent layers can include a positive temperature coefficient (PTC) material such that the respective temperature-dependent electrical property includes a resistance that increases with an increase in temperature. In some embodiments, the positive temperature coefficient material can include a polymeric positive temperature coefficient (PPTC) material. In some embodiments, the electrical device can be a resettable fuse.

In some embodiments, the first and second temperature-dependent layers can be formed from same material.

In some embodiments, a change in dimension of each of the first and second temperature-dependent layers can result in the change in separation distance between the first and third electrodes. The change in temperature can include an increase in temperature, and the change in separation distance between the first and third electrodes can include an increase in separation distance between the first and third electrodes.

In some embodiments, the first and third terminals can be configured to include respective gap portions, such that the gap portion of the first terminal maintains a gap dimension with respect to the gap portion of the third terminal. The gap dimension can be within a selected range during the relative movement. The selected range of the gap dimension can be selected to allow a solder material to flow from one gap portion to the other gap portion during a soldering process to thereby allow the first and third terminals to become electrically connected.

In some embodiments, a change in dimension of each of the first and second temperature-dependent layers can include a thickness dimension change in a first direction that is normal to a plane of the first electrode. The gap portion of each of the first and third terminals can include an edge extending in a direction approximately parallel to the first direction. The edge of each of the first and second terminals can define one side of a respective tab having a width. The width of the tab of the first terminal can be approximately the same as the width of the tab of the third terminal. The width of the tab of the first terminal can be greater than the width of the tab of the third terminal.

In some embodiments, the first terminal can include a flat portion defining a plane that is approximately parallel with a plane of the first electrode, with the flat portion having an inner edge, an outer edge, a thickness and a mounting side. The inner edge of the flat portion of the first terminal can be connected to an edge of the first electrode by a connecting portion. The second terminal can include a flat portion defining a plane that is approximately parallel with a plane of the second electrode, with the flat portion having an inner edge, an outer edge, a thickness and a mounting side. The outer edge of the flat portion of the second terminal can be connected to an edge of the second electrode by a connecting portion.

In some embodiments, the flat portion of the first terminal can define a cutout along the outer edge, and the third terminal can include a terminal edge with a tab extending therefrom. The tab can be dimensioned to be at least partially within the cutout of the flat portion of the first terminal such that the cutout provides the gap portion for the first terminal and the tab provides the gap portion for the third terminal.

In some embodiments, the multi-layer electrical device can further include a third temperature-dependent layer implemented over the third electrode, and a fourth electrode over the third temperature-dependent layer. The fourth electrode can be electrically connected to a fourth terminal on the second side of the multi-layer electrical device. The second and fourth terminals can be dimensioned to allow movement relative to each other to accommodate a change in dimension of each of the second and third temperature-dependent layers resulting from a change in temperature, and to allow a solder to provide a connection therebetween when the multi-layer electrical device is soldered on a mounting surface.

In some implementations, the present disclosure relates to a method for manufacturing a multi-layer electrical device. The method includes implementing multiple electrodes that are connected to respective terminals. The method further includes dimensioning at least two selected terminals to allow movement relative to each other to accommodate a change in separation distance of the respective electrodes resulting from a change in temperature, and to allow a solder to provide a connection therebetween when the multi-layer electrical device is soldered on a mounting surface.

In some embodiments, the method can further include forming or providing a temperature-dependent layer between each neighboring pair of electrodes. The temperature-dependent layer can include a material having a temperature-dependent electrical property. The temperature-dependent layer can result in the change in separation distance of the respective neighboring pair of electrodes with the change in temperature.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows a multi-layer electrical device having two layers.

FIG. 2 shows an example configuration where three nodes associated with three respective electrodes are electrically connected to two nodes.

FIG. 3 shows a multi-layer electrical device having three layers.

FIG. 4 shows an example configuration where four nodes associated with four respective electrodes are electrically connected to two nodes.

FIGS. 5A to 5E show various views of an example multi-layer electrical device implemented as a surface-mount technology (SMT) device.

FIG. 6A shows the same view of the multi-layer electrical device as FIG. 5B when positioned on a mounting surface.

FIG. 6B shows an end view from a first side of the multi-layer electrical device of FIG. 6A.

FIG. 6C shows an enlarged view of a portion of FIG. 6A.

FIG. 6D shows an enlarged view of a portion of FIG. 6B.

FIG. 7A shows the multi-layer electrical device of FIG. 6A undergoing thermal expansion due to a rise in temperature.

FIG. 7B shows an end view, similar to FIG. 6B, of the multi-layer electrical device undergoing thermal expansion.

FIG. 7C shows an enlarged view of a portion of FIG. 7A when the multi-layer electrical device is in the thermally expanded state.

FIG. 7D shows an enlarged view of a portion of FIG. 7B when the multi-layer electrical device is in the thermally expanded state.

FIG. 8A shows the multi-layer electrical device of FIG. 7A mounted to a mounting surface by a soldering process.

FIG. 8B shows an end view, similar to FIG. 7B, of the multi-layer electrical device mounted to the mounting surface.

FIG. 8C shows an enlarged view of a portion of FIG. 8A when the multi-layer electrical device is mounted to the mounting surface.

FIG. 8D shows an enlarged view of a portion of FIG. 8B when the multi-layer electrical device is mounted to the mounting surface.

FIGS. 9A to 9C show that in some embodiments, a multi-layer electrical device having one or more features as described herein can be configured to desirably provide a good engagement between each of a plurality of terminals and a mounting surface during a mounting process.

FIG. 10 shows a multi-layer electrical device having three temperature-dependent layers and four electrodes configured so that the electrodes are electrically connected to two nodes, similar to the example of FIG. 4.

FIG. 11 shows an underside view of a multi-layer electrical device having first, second and third terminals, where the first and second terminals are configured to provide contacts with a mounting surface, similar to the examples of FIGS. 5-9.

FIG. 12A shows a perspective view of a multi-layer electrical device having two temperature-dependent layers and three corresponding electrodes, similar to the examples of FIGS. 1 and 2.

FIG. 12B shows an end view of the multi-layer electrical device of FIG. 12A in a non-expanded state.

FIG. 12C shows the same end view of the multi-layer electrical device of FIG. 12A in an expanded state.

FIGS. 13A and 13B show non-expanded and expanded states of a multi-layer electrical device that is similar to the multi-layer electrical device of FIGS. 12A to 12C, but configured to reduce the likelihood of tip-over when its third terminal is separated from a mounting surface.

### DETAILED DESCRIPTION OF SOME EMBODIMENTS

The headings provided herein, if any, are for convenience only and do not necessarily affect the scope or meaning of the claimed invention.

Described herein are examples related to multi-layer electrical devices that are configured to, among others, provide an improved mounting process. For the purpose of description, it will be understood that a multi-layer electrical device can include a plurality of layers with each layer being formed from a material having an electrical property. Each of such a plurality of layers can all be formed from same material, each layer can be formed from a different material, or any combination thereof. Each layer can have first and second surfaces (e.g., opposing surfaces), and an electrode can be provided on each of such surfaces.

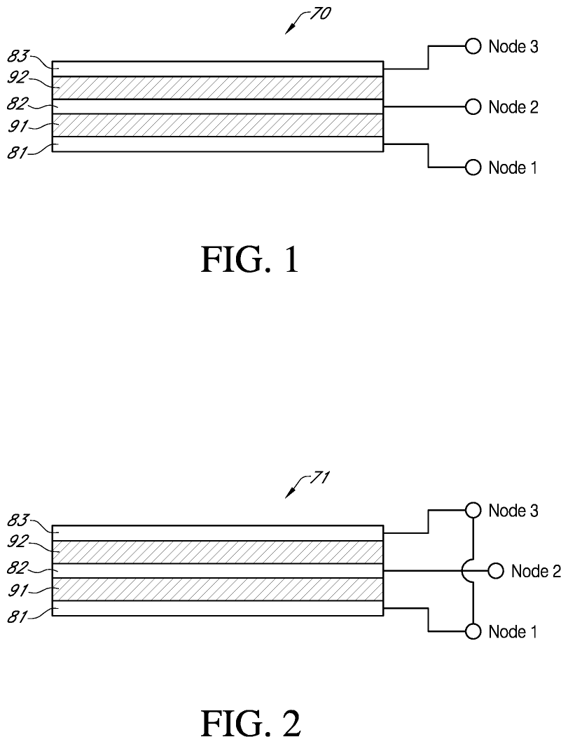

For example, FIG. 1 shows a multi-layer electrical device 70 having two layers 91, 92. The first layer 91 is shown to have first and second surfaces (e.g., lower and upper surfaces when oriented as shown), and an electrode is shown to be provided on each of such first and second surfaces. More particularly, an electrode 81 is shown to be implemented on the first side of the first layer 91, and an electrode 82 is shown to be implemented on the second side of the first layer 91. Similarly, the electrode 82 is shown to be implemented on the first side of the second layer 92, and an electrode 83 is shown to be implemented on the second side of the second layer 92.

In the foregoing example, the electrode 82 between the first and second layers 91, 92 is configured as a common electrode. However, it will be understood that the region between the first and second layers 91, 92 can be provided with separate electrodes that may or may not be electrically connected.

In the example of FIG. 1, the three electrodes 81, 82, 83 are shown to be electrically connected to respective nodes (Node 1, Node 2, Node 3). In some embodiments, such three nodes can be electrically separate nodes, or be electrically connected to two nodes, when the multi-layer electrical device 70 is mounted to a circuit board.

FIG. 2 shows an example configuration 71 where the three nodes associated with the respective electrodes 81, 82, 83 are electrically connected to two nodes. More particularly, the first and third nodes (Node 1 and Node 3) associated with the first and third electrodes 81, 83 are shown to be electrically connected, and the second node (Node 2) associated with the second electrode 82 is shown to remain by itself.

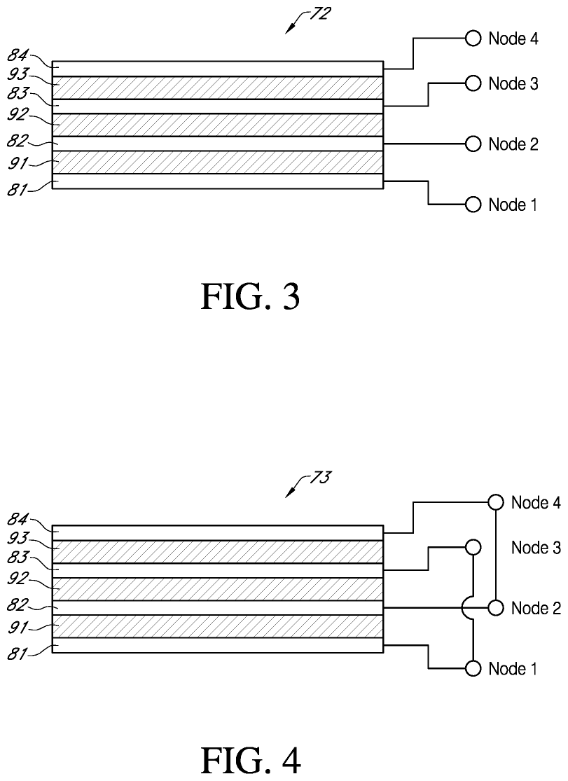

In another example, FIG. 3 shows a multi-layer electrical device 72 having three layers 91, 92, 93. The first layer 91 is shown to have first and second surfaces (e.g., lower and upper surfaces when oriented as shown), and an electrode is shown to be provided on each of such first and second surfaces. More particularly, an electrode 81 is shown to be implemented on the first side of the first layer 91, and an electrode 82 is shown to be implemented on the second side of the first layer 91. The electrode 82 is shown to be implemented on the first side of the second layer 92, and an electrode 83 is shown to be implemented on the second side of the second layer 92. The electrode 83 is shown to be implemented on the first side of the third layer 93, and an electrode 84 is shown to be implemented on the second side of the third layer 93.

In the foregoing example, the electrode 82 between the first and second layers 91, 92 is configured as a common electrode, and the electrode 83 between the second and third layers 92, 93 is configured as a common electrode. However, it will be understood that the region between the first and second layers 91, 92 can be provided with separate electrodes that may or may not be electrically connected, and/or the region between the second and third layers 92, 93 can be provided with separate electrodes that may or may not be electrically connected.

In the example of FIG. 3, the four electrodes 81, 82, 83, 84 are shown to be electrically connected to respective nodes (Node 1, Node 2, Node 3, Node 4). In some embodiments, such four nodes can be electrically separate nodes, or be electrically connected to two or more nodes, when the multi-layer electrical device 72 is mounted to a circuit board.

FIG. 4 shows an example configuration 73 where the four nodes associated with the respective electrodes 81, 82, 83, 84 are electrically connected to two nodes. More particularly, the first and third nodes (Node 1 and Node 3) associated with the first and third electrodes 81, 83 are shown to be electrically connected, and the second and fourth nodes (Node 2 and Node 4) associated with the second and fourth electrodes 82, 84 are shown to be electrically connected.

It is noted that when a multi-layer electrical device, such as any one of the examples of FIGS. 1 to 4, is subjected to a change in temperature, some or all of the various parts can undergo thermal expansion or contraction. For example, an increase in temperature can result in a part of a multi-layer electrical device to undergo a thermal expansion. It will be understood that while various examples are described in the context of such a positive thermal expansion (where an increase in temperature results in an increase in a dimension), one or more features of the present disclosure can also be utilized in situations involving a negative thermal expansion (where an increase in temperature results in a decrease in a dimension).

It is also noted that in many applications, each layer between respective electrodes in a multi-layer electrical device (such as any one of the examples of FIGS. 1 to 4) is formed from a material (e.g., a non-metal material) to provide a desired electrical property. For example, such a layer can be formed from a polymer or polymer-based material such as a polymeric positive temperature coefficient (PPTC) material. Such a PPTC material includes a temperature-dependent electrical property where the material has a low resistivity (and therefore a high conductivity) at a normal operating temperature, and an increase in resistivity (and therefore a decrease in conductivity) with an increase in temperature. For example, a multi-layer electrical device having layers of PPTC material can be configured to provide a resettable fuse functionality between a first node (e.g., Nodes 1 and 3 electrically connected together in FIG. 2) and a second node (Node 2 in FIG. 2).

It will be understood that a multi-layer electrical device having one or more features as described herein can be configured to include materials other than the foregoing PPTC or other polymer-based material. For example, a multi-layer electrical device having metal-oxide layers can be implemented as a metal-oxide varistor. In another example, a multi-layer electrical device having dielectric layers can be implemented as a capacitor.

It will also be understood that the above-discussed increase in temperature resulting in a thermal expansion of a multi-layer electrical device may or may not be the same increase in temperature resulting in manifestation of a change in electrical property of the associated layers of material such as the PPTC material. For example, a thermal expansion of a multi-layer electrical device can occur due to heat being applied during a process when the multi-layer electrical device is soldered onto a circuit board; whereas an increase in resistivity of the PPCT material of the multi-layer electrical device can result from an increase in temperature associated with an increase in current through the multi-layer electrical device.

In some embodiments, a multi-layer electrical device can be configured to accommodate a thermal expansion that occurs during a process when the multi-layer electrical device is being mounted onto a circuit board. Various examples of multi-layer electrical devices that provide such a configuration are described herein in greater detail.

In some embodiments, a multi-layer electrical device can be implemented as a surface-mount technology (SMT) device configured to be mounted onto a surface of a circuit board such as s printed circuit board (PCB). In many applications, such an SMT device is also referred to as a surface-mount device (SMD). It will be understood that one or more features of the present disclosure can also be implemented in non-SMT electrical devices.

In some embodiments, a multi-layer electrical device can include multiple electrodes connected to respective terminals. A temperature-dependent layer can be implemented between each neighboring pair of electrodes. At least two selected terminals can be configured to allow movement relative to each other to accommodate a change in separation distance of the respective electrodes resulting from a change in temperature, and to allow a solder to provide a connection therebetween when the multi-layer electrical device is soldered on a mounting surface. Examples related to such a multi-layer electrical device are described herein in greater detail.

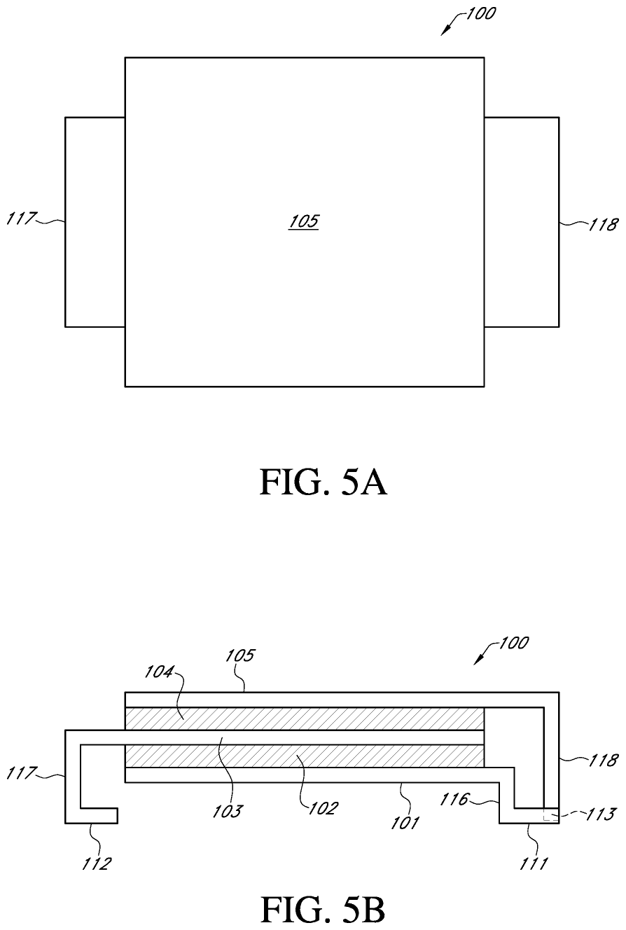

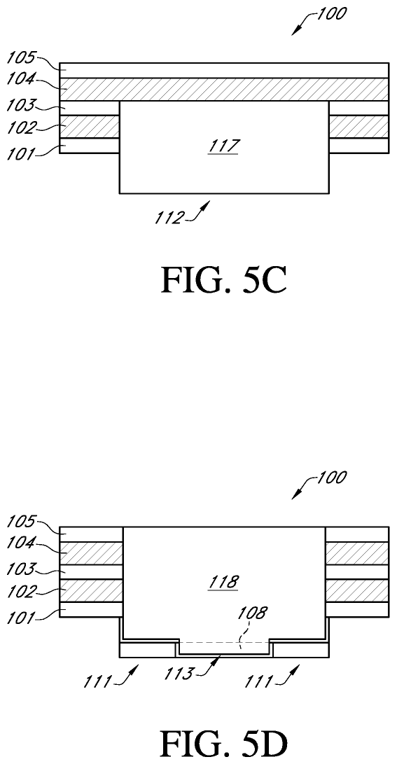

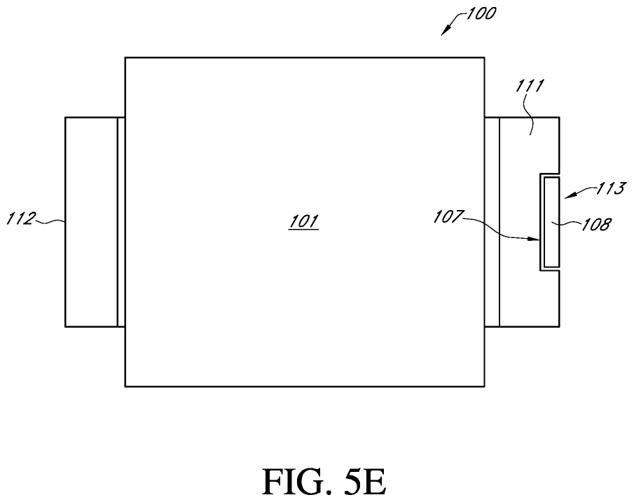

FIGS. 5A to 5E show various views of an example multi-layer electrical device 100 implemented as an SMT device. FIG. 5A shows an upper plan view of the multi-layer electrical device 100 when the device 100 is on a mounting surface. FIG. 5B shows a side view 100 of the multi-layer electrical device 100 of FIG. 5A; FIG. 5C shows an end view of the multi-layer electrical device 100 of FIG. 5A; FIG. 5D shows another end view of the multi-layer electrical device 100 of FIG. 5A; and FIG. 5E shows an underside view of the multi-layer electrical device 100 of FIG. 5A.

Referring to FIGS. 5A to 5E, the multi-layer electrical device 100 is shown to include first, second and third electrodes 101, 103, 105 that are connected to respective first, second and third terminals 111, 112, 113. More particularly, the first electrode 101 is connected to the first terminal 111 through a connecting member 116; the second electrode 103 is connected to the second terminal 112 through a connecting member 117; and the third electrode 105 is connected to the third terminal 113 through a connecting member 118.

In the example of FIGS. 5A to 5E, the first and third electrodes 101, 105 are to be electrically connected once soldered onto a mounting surface to form a first node, and the second electrode 103 is to be electrically connected to a second node by itself. Such an electrical connection between the first and third electrodes 101, 105 can be made through the first and third terminals 111, 113 as described herein.

Implemented between a pair of neighboring electrodes is a temperature-dependent layer. More particularly, a first temperature-dependent layer 102 is shown to be implemented between the first and second electrodes 101, 103; and a second temperature-dependent layer 104 is shown to be implemented between the second and third electrodes 103, 105. Thus, the alternating arrangement of the electrodes 101, 103, 105 and the temperature-dependent layers 102, 104 forms a multi-layer configuration.

In some embodiments, each of the first and second temperature-dependent layers 102, 104 can be formed from a polymer or polymer-based material such as a polymeric positive temperature coefficient (PPTC) material. Such a PPTC material can include a temperature-dependent electrical property where the material has a low resistivity (and therefore a high conductivity) at a normal operating temperature, and an increase in resistivity (and therefore a decrease in conductivity) with an increase in temperature.

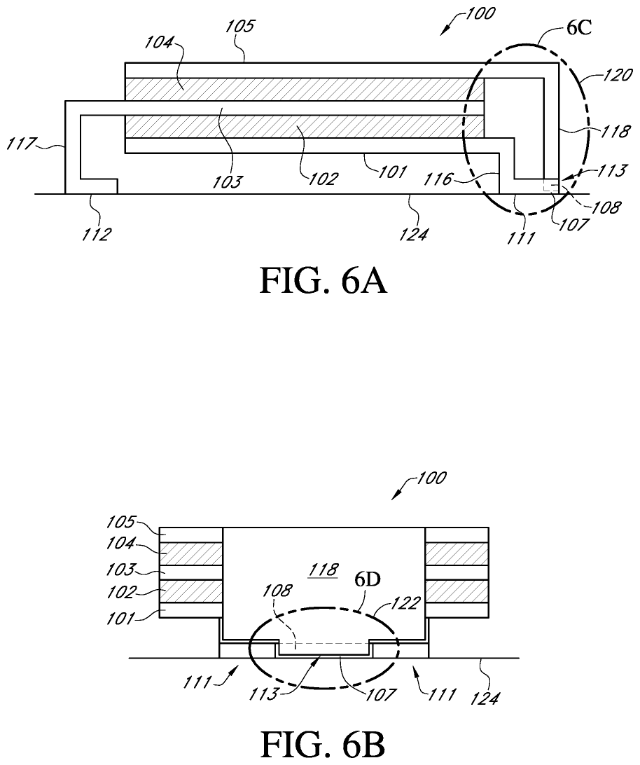

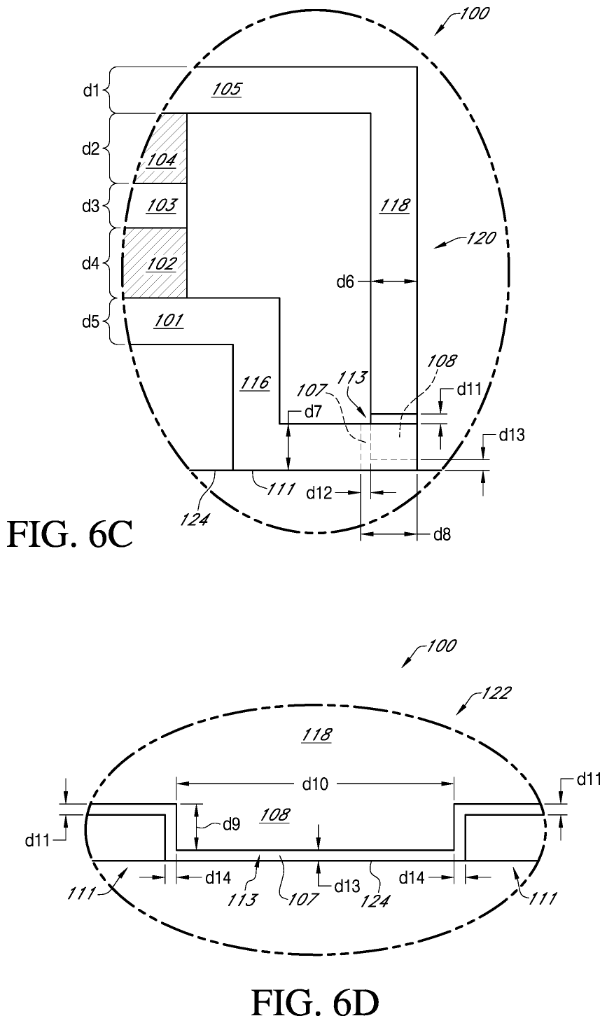

FIG. 6A shows the same view of the multi-layer electrical device 100 as FIG. 5B when positioned on a mounting surface 124. FIG. 6C shows an enlarged view of a portion generally indicated in FIG. 6A as 120. FIG. 6B shows an end view from a first side of the multi-layer electrical device 100 with an arrangement (generally indicated as 122) of the first and third terminals 111, 113. FIG. 6D shows an enlarged view of the arrangement 122 of FIG. 6B.

In the example shown in FIGS. 5 and 6, the third terminal 113 is shown to include a tab 108 that extends downward from a lower edge of the connecting member 118 that connect the third electrode 105 to the third terminal 113. Such a tab of the third terminal 113 is shown to be positioned within a cutout 107 formed on an outer edge of the first terminal 111.

Configured in the foregoing manner, and as shown in the enlarged views of FIGS. 6C and 6D, various dimensions as listed in Table 1 can be provided.

TABLE 1

| Dimension | Detail |
|---|---|
| d1 | Average thickness of the third electrode 105 |
| d2 | Average thickness of the second temperature- |
| | dependent layer 104 |
| d3 | Average thickness of the second electrode 103 |
| d4 | Average thickness of the first temperature- |
| | dependent layer 102 |
| d5 | Average thickness of the first electrode 101 |
| d6 | Average thickness of the third terminal 113 |
| d7 | Average thickness of the first terminal 111 |
| d8 | Average depth of the cutout 107 on the outer |
| | edge of the first terminal 111 |
| d9 | Average length of the tab 108 of the third |
| | terminal 113 |
| d10 | Average width of the tab 108 of the third |
| | terminal 113 |
| d11 | Average gap between lower edge of the connecting |
| | member 118 and upper surface of the first |
| | terminal 111 |
| d12 | Average gap between the tab 108 of the third |
| | terminal 113 and the wall of the cutout 107 |
| | of the first terminal 111 |
| d13 | Average gap between the end of the tab 108 |
| | of the third terminal 113 and the mounting |
| | surface 124 |
| d14 | Average gap between the side of the tab 108 |
| | of the third terminal 113 and the corresponding |
| | side of the cutout 107 of the first terminal 111 |

Referring to FIGS. 6A to 6D, one can see that the third terminal 113 is able to move relative to the first terminal 111 while maintaining at least some of the gaps listed in Table 1, within some acceptable ranges.

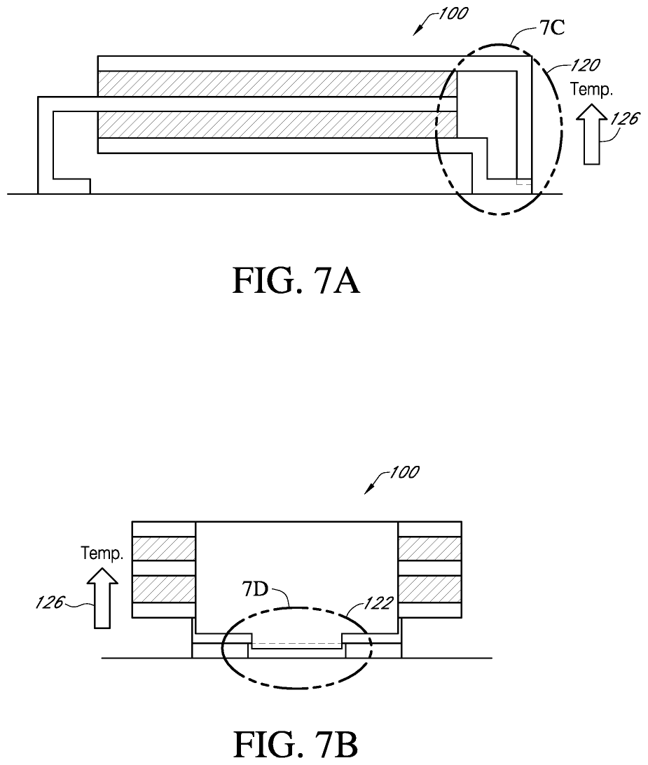

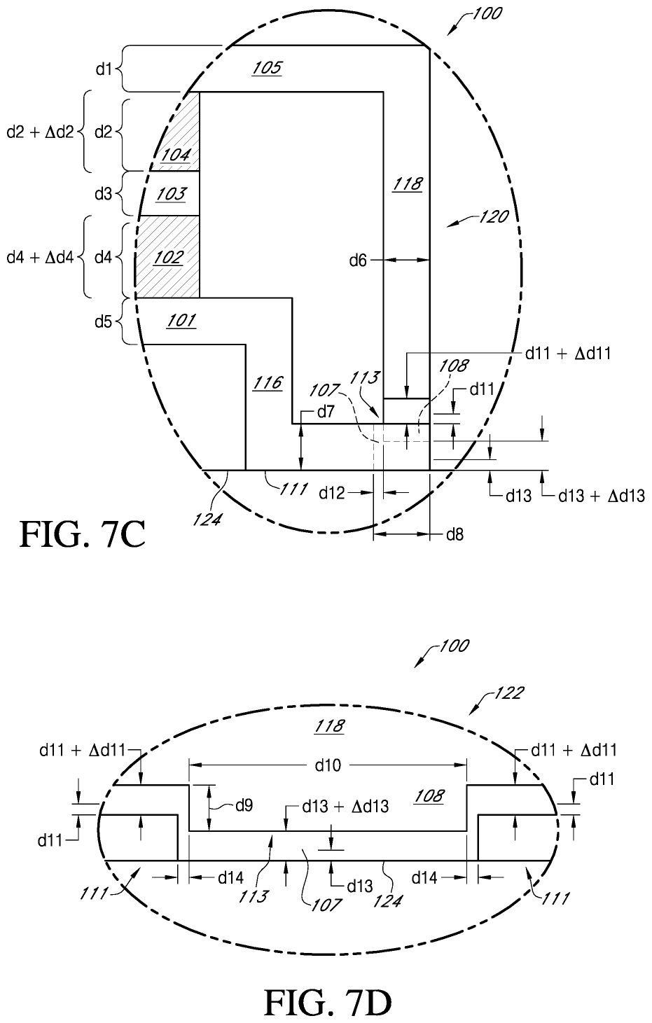

For example, FIG. 7A shows the multi-layer electrical device 100 of FIG. 6A undergoing thermal expansion due to a rise in temperature (126) (e.g., due to heating for a soldering process). FIG. 7B shows an end view, similar to FIG. 6B, of the multi-layer electrical device 100 undergoing thermal expansion. FIG. 7C shows an enlarged view of a portion generally indicated in FIG. 7A as 120 when the multi-layer electrical device 100 is in the thermally expanded state. FIG. 7D shows an enlarged view of an arrangement generally indicated in FIG. 7B as 122 when the multi-layer electrical device 100 is in the thermally expanded state.

In FIGS. 7C and 7D, the thermally expanded state results from expansions including expansions of the temperature-dependent layers 102, 104 resulting in increases their respective thicknesses. Accordingly, the separation distance d4 between the first and second electrodes 101, 103 increases by Δd4, and the separation distance d2 between the second and third electrodes 103, 105 increases by Δd2. Since the second terminal (112 in FIG. 6A) connected to the second electrode 103 is by itself for the second node, there is no relative movement of the second terminal 112 to be concerned with. However, the expansions of the first and second temperature-dependent layers 102, 104 collectively result in the first and third electrodes 101, 105 to become separated; thus, the respective first and third terminals 111, 113 can be configured as described herein to accommodate such an increase in separation of the same-node (first node) electrodes.

Table 2 lists the various dimensions of Table 1 in the thermally expanded state of FIG. 7D.

TABLE 2

| Dimension | Detail |
|---|---|
| d1 | Average thickness of the third electrode 105 |
| | in the expanded state |
| d2 + Δd2 | Average thickness of the second temperature- |
| | dependent layer 104 in the expanded state |
| d3 | Average thickness of the second electrode |
| | 103 in the expanded state |
| d4 + Δd4 | Average thickness of the first temperature-dependent |
| | layer 102 in the expanded state |
| d5 | Average thickness of the first electrode 101 |
| | in the expanded state |
| d6 | Average thickness of the third terminal 113 |
| | in the expanded state |
| d7 | Average thickness of the first terminal 111 |
| | in the expanded state |
| d8 | Average depth of the cutout 107 on the outer edge of |
| | the first terminal 111 in the expanded state |
| d9 | Average length of the tab 108 of the third terminal |
| | 113 in the expanded state |
| d10 | Average width of the tab 108 of the third terminal |
| | 113 in the expanded state |
| d11 + Δd11 | Average gap between lower edge of the connecting |
| | member 118 and upper surface of the first |
| | terminal 111 in the expanded state |
| d12 | Average gap between the tab 108 of the third terminal |
| | 113 and the wall of the cutout 107 of the |
| | first terminal 111 in the expanded state |
| d13 + Δd13 | Average gap between the end of the tab 108 of the third |
| | terminal 113 and the mounting surface 124 in |
| | the expanded state |
| d14 | Average gap between the side of the tab 108 of the |
| | third terminal 113 and the corresponding side |
| | of the cutout 107 of the first terminal 111 |
| | in the expanded state |

In the example expanded state of FIGS. 7C and 7D, and Table 2, it is assumed that expansions associated with the electrodes 101, 103, 105 and respective terminals 111, 112, 113 are negligible or sufficiently small when compared to the expansions associated with the temperature-dependent layers 102, 104. For example, metals or alloys utilized as electrodes typically have linear temperature expansion coefficient (α, in units of 10⁻⁶ m/(m ° C.)) values below 20, while polymeric materials such as PPTC materials have much higher linear temperature expansion coefficient values (e.g., above 50 or 100). It is noted that even if the expansions associated with the electrodes and the terminals are non-negligible, one or more features of the present disclosure can still be implemented.

Referring to the thermally expanded state of FIGS. 7C and 7D, and the corresponding dimensions in Table 2, a soldering process can be applied to mount the multi-layer electrical device 100 to the mounting surface 124. When solder is allowed to flow during such a process, at least some of the gaps in the thermally expanded state can remain sufficiently small to be filled with solder material, thereby securing the first and third terminals 111, 113 together and thereby electrically connecting the first and third electrodes 101, 105.

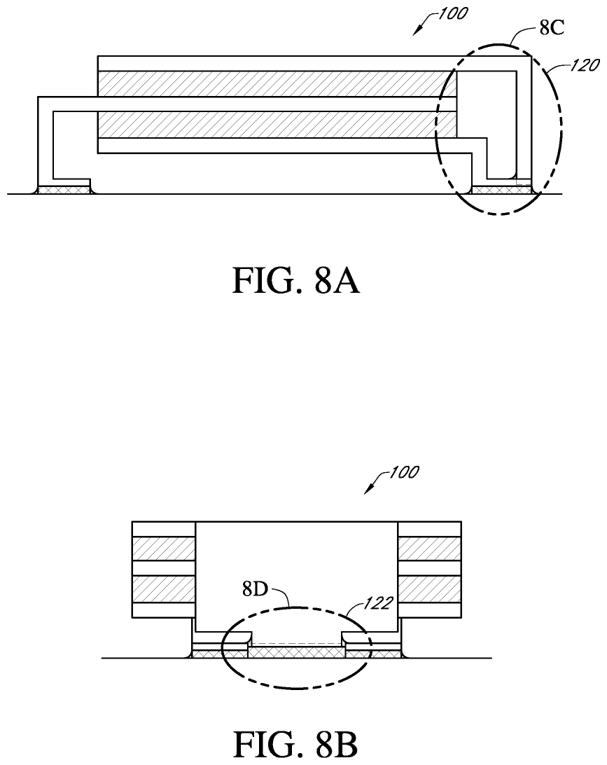

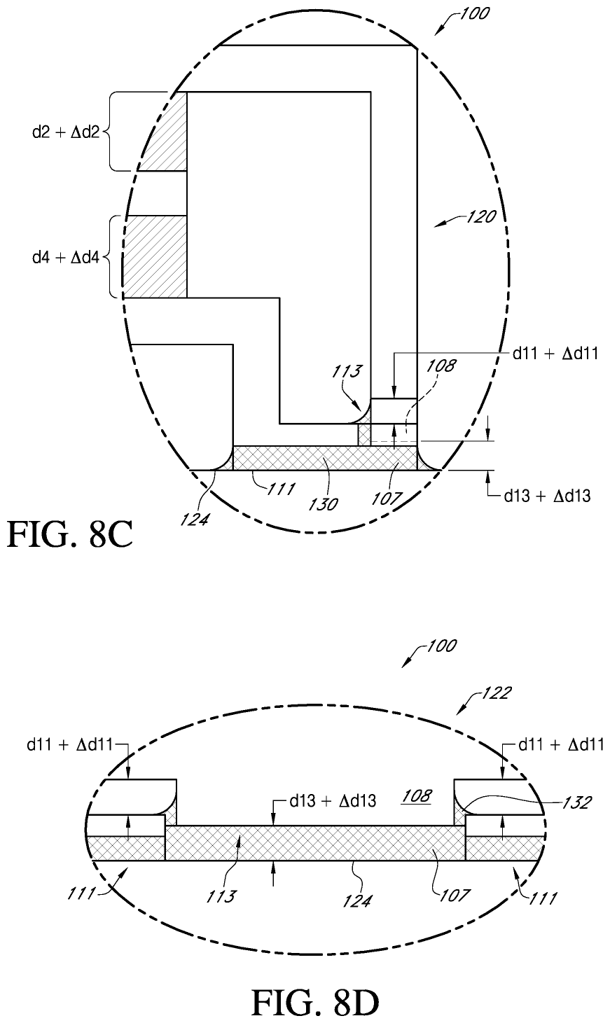

For example, FIG. 8A shows the multi-layer electrical device 100 of FIG. 7A mounted to a mounting surface by a soldering process. FIG. 8B shows an end view, similar to FIG. 7B, of the multi-layer electrical device 100 mounted to the mounting surface. FIG. 8C shows an enlarged view of a portion generally indicated in FIG. 8A as 120 when the multi-layer electrical device 100 is mounted to the mounting surface. FIG. 8D shows an enlarged view of an arrangement generally indicated in FIG. 8B as 122 when the multi-layer electrical device 100 is mounted to the mounting surface.

More particularly, and referring to the enlarged views of FIGS. 8C and 8D, solder material 130 is shown to have reflowed into the cutout 107 of the first terminal 111 with sufficient height (e.g., at least d13+Δd13) so as to secure the tab 108 of the third terminal 113 to the first terminal 111 and the mounting surface 124. The solder material 130 can also flow higher to fill some or all of the gaps between the tab 108 of the third terminal 113 and respective portions of the cutout 107 of the first terminal 111. For example, the gaps indicated in FIGS. 7C and 7D as d12 and d14 can be filled with the solder material 130.

In the example described above in reference to FIGS. 7 and 8, it is noted that the first and second terminals 111, 112 are secured to the mounting surface 124 by the respective reflowed solder structures. The third terminal 113 is secured to the first terminal 111 by the respective reflowed solder structure. Accordingly, the third terminal 113 is also secured to the mounting surface 124, thereby securing the multi-layer electrical device 100 to the mounting surface 124.

It is also noted that when the multi-layer electrical device 100 is mounted to the mounting surface 124, as in the example of FIGS. 8A to 8D, the temperature-dependent layers 102, 104 (such as PPTC layers) are in an expanded state, and the electrodes 101, 103, 105 and their respective terminals 111, 112, 113 are in relative positions to accommodate the expanded state of the temperature-dependent layers 102, 104. When the multi-layer electrical device 100 cools after the mounting process, the PPTC layers 102, 104 will have a tendency to contract as the temperature decreases. If each PPTC layer is joined to the electrodes on both sides (e.g., by solder joints formed by solder paste at an interface surface on each side of the PPTC layer, followed by a reflow process preferably at a temperature higher than the temperature resulting in the expanded state of the PPTC layer), the contracting PPTC layers 102, 104 will result in mechanical stress being introduced to some or all of the electrode/terminal assemblies associated with the electrodes 101, 103, 105.

However, in some embodiments, a multi-layer electrical device being fixed to a mounting surface while temperature-dependent layers (such as PPTC layers) are in an expanded state is preferable (even with the foregoing mechanical stress resulting from cooling) over a situation where temperature-dependent layers are not able to freely expand during a mounting process. For example, in the context of temperature-dependent layers being PPTC layers, it is noted that the positive temperature coefficient (PTC) effect arises at least in part due to the volume expansion of polymer matrix to break up the conductive path through a given PPTC layer. Thus, when a PPTC volume is constrained, the level of PTC effect will be low. Further, such a constrained PPTC volume with low PTC effect will likely have a higher leakage current, and therefore result in premature damage or destruction of the corresponding multi-layer electrical device.

In the examples described above in reference to FIGS. 6 to 8, the temperature-dependent layers 102, 104 (such as PPTC layers) are allowed to expand during a mounting process, due to the configuration of the electrodes 101, 103, 105 and their respective terminals 111, 112, 113. Further, the terminals 111, 112, 113 can be configured as described herein to allow the multi-layer electrical device 100 to be mounted and secured to a mounting surface while the temperature-dependent layers 102, 104 are in an expanded state.

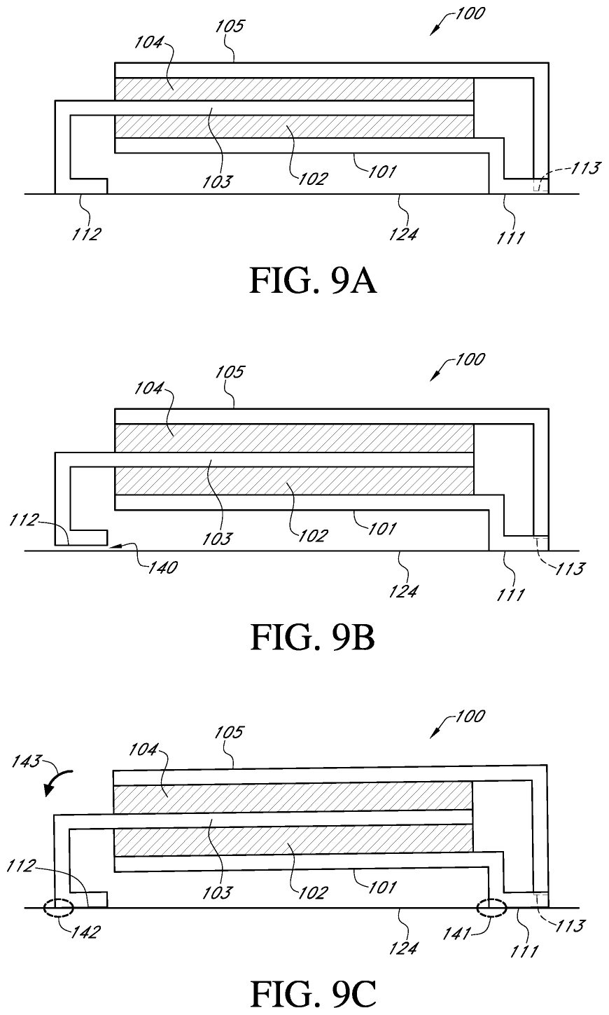

FIGS. 9A to 9C show that in some embodiments, a multi-layer electrical device having one or more features as described herein can be configured to desirably provide a good engagement between each of a plurality of terminals and a mounting surface during a mounting process. For example, FIG. 9A shows a side view of a multi-layer electrical device 100 in a thermally un-expanded state and positioned on a mounting surface 124, similar to the example of FIG. 6A. In such an example configuration, the electrodes 101, 103, 105, the respective terminals 111, 112, 113, and the respective connecting members (116, 117, 118 in FIG. 6A) can be dimensioned such that the surfaces of the first and second terminals 111, 112 are co-planar (or approximately co-planar) with the mounting surface 124.

For such a configuration, FIG. 9B shows the multi-layer electrical device 100 in a thermally expanded state, where the temperature-dependent layers 102, 104 have expanded due to heat being applied for the mounting process. Accordingly, separation distance between the first and second electrodes 101, 103 increases due to the expansion of the first temperature-dependent layer 102, and separation distance between the second and third electrodes 103, 105 increases due to the expansion of the second temperature-dependent layer 104.

As described herein, net effect of the foregoing separation distances of the electrodes 101, 103, 105 results in a relative movement between the first and third terminals 111, 113; and such terminals can be configured to accommodate such a movement and to allow securing of both terminals to the mounting surface 124. In FIG. 9B, an effect of the increase in separation distance between the first and second electrodes 101, 103 is depicted as a gap 140 being provided between the second terminal 112 and the mounting surface 124.

FIG. 9C shows the multi-layer electrical device 100 tilted over to the second terminal (112) side due to the gap 140 of FIG. 9B. Accordingly, the multi-layer electrical device 100 still maintains two contact locations 141, 142 in the tilted orientation. More particularly, the first contact location 141 is shown to be along one edge of the first terminal 111, and the second contact location 142 is shown to be along one edge of the second terminal 112.

It is noted that even though the surfaces of first and second terminals 111, 112 are no longer co-planar with the mounting surface 124 (as in FIG. 9A), the first and second contact locations 141, 142 remain co-planar with the mounting surface 124. Accordingly, during a reflow process, effective solder structures can be formed for the first and second terminals 111, 112 through the respective contact locations 141, 142.

In the example of FIGS. 9A to 9C, the multi-layer electrical device 100 is configured to provide co-planarity of the surfaces of the engaging terminals (e.g., 111, 112) with the plane of the mounting surface when in a non-expanded state. It will be understood that a multi-layer electrical device having one or more features as described herein can also be configured in other manners. For example, a multi-layer electrical device can be configured to be pre-tilted when in a non-expanded state, and to provide a co-planar arrangement of the surfaces of the terminals with the mounting surface when in an expanded state.

In the examples described in reference to FIGS. 5 to 9, a multi-layer electrical device is shown to include two temperature-dependent layers and three electrodes. It will be understood that in some embodiments, other numbers of temperature-dependent layers and electrodes can be implemented.

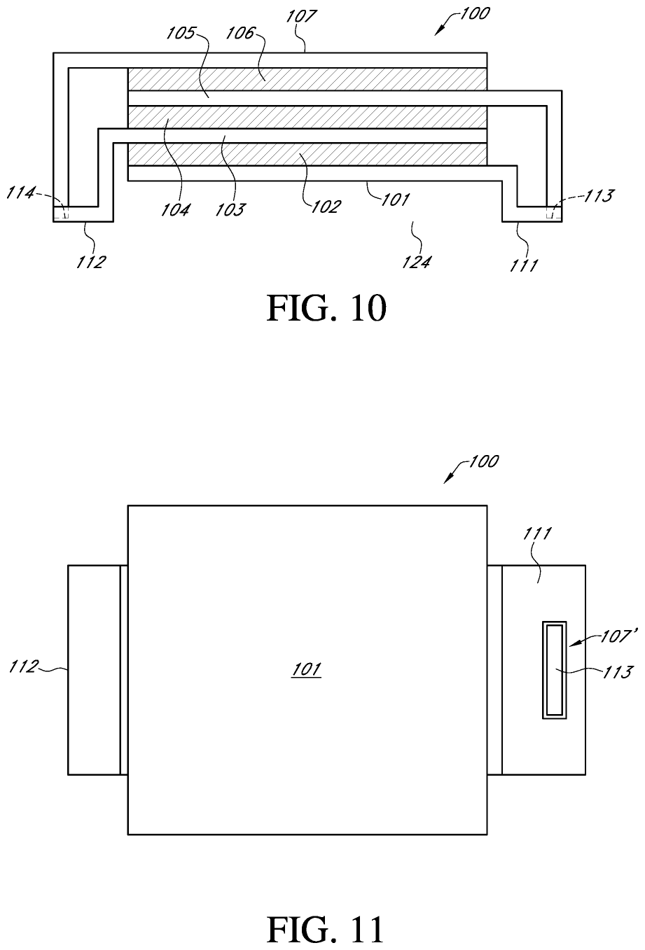

For example, FIG. 10 shows a multi-layer electrical device 100 having three temperature-dependent layers 102, 104, 106 and four electrodes 101, 103, 105, 107. In some embodiments, such a multi-layer electrical device can be configured so that the electrodes 101, 103, 105, 107 are electrically connected to two nodes, similar to the example of FIG. 4.

Accordingly, in the example of FIG. 10, first and third terminals 111, 113 associated with respective first and third electrodes 101, 105 can be configured as described herein in reference to FIGS. 5 to 9. In some embodiments, second and fourth terminals 112, 114 associated with respective second and fourth electrodes 103, 107 can also be configured in a similar manner to allow relative movement between the second and fourth terminals 112, 114 resulting from expansion of the temperature-dependent layers 102, 104, 106.

In the examples described in reference to FIGS. 5 to 9, a multi-layer electrical device is shown to include a pair of terminals configured to accommodate thermal expansion of a plurality of temperature-dependent layers while allowing such terminals to be secured to a mounting surface. In such examples, the terminal 111 in contact with the mounting surface includes a cutout 107 dimensioned to receive a tab 108 of the other terminal 113 and to allow the tab 108 to move relative to the cutout 107 as the temperature-dependent layers thermally expand. Such an example cutout is depicted as being along the outer edge of the terminal 111, such that the cutout 107 has an open side. It will be understood that cutout and tab providing similar functionalities as the foregoing example cutout 107 and tab 108 can be configured in different manner.

For example, FIG. 11 shows an underside view of a multi-layer electrical device 100 having first, second and third terminals 111, 112, 113, where the first and second terminals 111, 112 are configured to provide contacts with a mounting surface, similar to the examples of FIGS. 5 to 9. In the example of FIG. 11, however, a cutout 107′ of the first terminal 111 is shown to be implemented such that all of the sides of the cutout 107′ are laterally within the area of the first terminal. Accordingly, the cutout 107′ does not have an open side as in the cutout 107 of the examples of FIGS. 5-9.

In the example of FIG. 11, the enclosed cutout 107′ can be dimensioned to allow relative movement of a tab of a third terminal 113, similar to the examples of FIGS. 5 to 9. Then, when the multi-layer electrical device 100 undergoes a soldering process, reflowed solder can secure the third terminal 113 to the first terminal 111 as described herein.

In the various examples described herein in reference to FIGS. 5 to 11, each multi-layer electrical device 100 includes two terminals having flat mounting surfaces. More particularly, each multi-layer electrical device 100 includes a first terminal 111 having a generally flat mounting surface and a second terminal 112 having a generally flat mounting surface, with at least the first terminal 111 being configured to allow movement of another terminal (e.g., a third terminal 113) relative thereto.

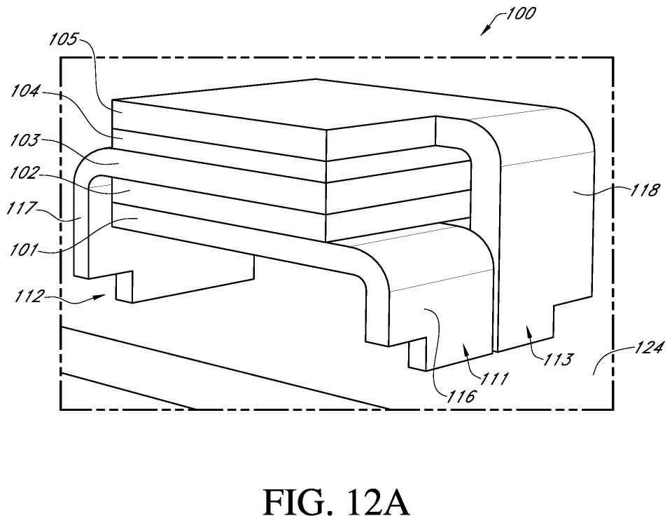

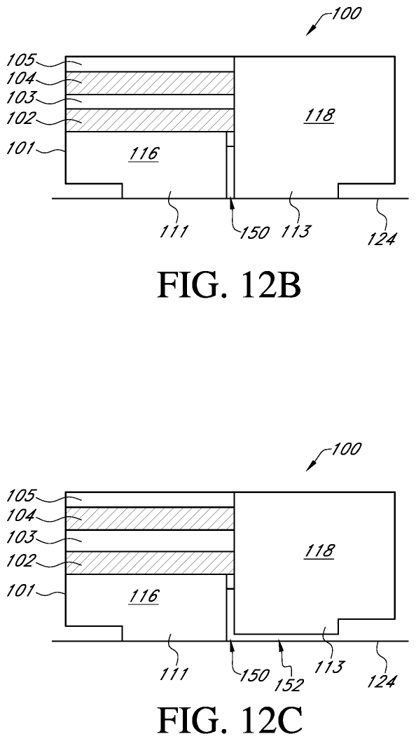

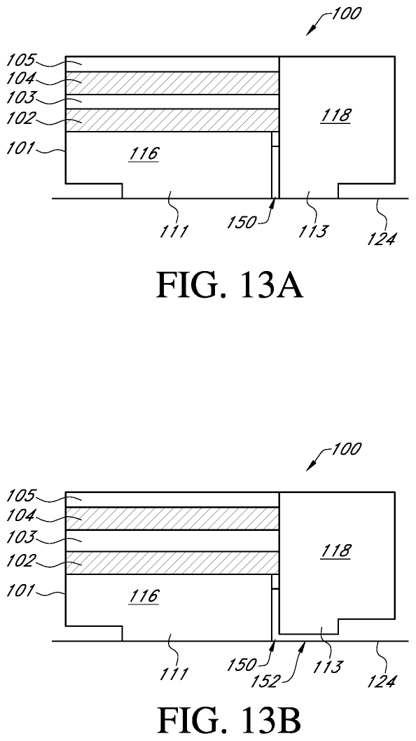

In some embodiment, a multi-layer electrical device can be configured without the foregoing flat mounting surfaces of terminals, yet allowing movement of one terminal relative to another terminal to thereby allow the two terminals to be secured to each other by reflowed solder during a soldering process. FIGS. 12 and 13 shows examples of such multi-layer electrical devices.

FIG. 12A shows a perspective view of a multi-layer electrical device 100 having two temperature-dependent layers 102, 104 and three corresponding electrodes 101, 103, 105, similar to the examples of FIGS. 1 and 2. FIG. 12B shows an end view of the multi-layer electrical device 100 in a non-expanded state, and FIG. 12C shows the same end view of the multi-layer electrical device 100 in an expanded state.

Referring to FIGS. 12A to 12C, the first electrode 101 is shown to be connected to a first terminal 111 through a connecting member 116; the second electrode 103 is shown to be connected to a second terminal 112 through a connecting member 117; and the third electrode 105 is shown to be connected to a third terminal 113 through a connecting member 118. Each of the three terminals 111, 112, 113 is shown to include a foot having an edge that either engages a mounting surface 124 or is close to the mounting surface 124, when the multi-layer electrical device 100 is positioned on the mounting surface 124.

In the example of FIGS. 12A to 12C, the connecting members 116, 118 of the first and third terminals 111, 113, respectively, can be configured to provide a gap 150 that allows the relative movement between the two terminals during a thermal expansion of the multi-layer electrical device 100. Configured in such a manner, at least some of the foot of each of the three terminals 111, 112, 113 is shown to be in engagement with the mounting surface 124 when the multi-layer electrical device 100 is in the non-expanded state of FIG. 12B. In the expanded state FIG. 12C, the foot of each of the first and second terminals 111, 112 is shown to be in engagement with the mounting surface 124, while the foot of the third terminal 113 is shown to be raised off of the mounting surface 124 (to provide a gap 152) due to the expansion of the temperature-dependent layers 102, 104.

In some embodiments, the gap 150 between the connecting members 116, 118 of the first and third terminals 111, 113 can be dimensioned to be within a range that allows a solder material to flow from one terminal (e.g., the first terminal 111) to the other terminal (e.g., the third terminal 113) during a soldering process, thereby allowing the two terminals to become electrically connected and secured to the mounting surface 124, even if one terminal (e.g., the third terminal 113) is not in direct contact with the mounting surface 124.

In the example orientation in the expanded state of FIG. 12C, the third terminal 113 of the multi-layer electrical device 100 is shown to be separated from the mounting surface to result in the gap 152. Accordingly, before reflowing of the solder material, the multi-layer electrical device 100 may or may not tip over towards the side of the third electrode 113 (e.g., the right side tipping downwards when viewed as in FIG. 12C). If the multi-layer electrical device 100 does not tip over, two contact locations can be provided by the first and second terminals 111, 112, and the third terminal 113 can be secured as described herein. If multi-layer electrical device 100 tips over, three contact locations can be provided by the first, second and third terminals 111, 112, 113, and the third terminal 113 can be further secured to the first terminal 111 as described herein.

In some embodiments, it may be preferable to have a multi-layer electrical device not to tip over when in an expanded state and before a reflow process. For example, FIGS. 13A and 13B show non-expanded and expanded states of a multi-layer electrical device 100 that is similar to the multi-layer electrical device 100 of FIGS. 12A to 12C, but configured to reduce the likelihood of tip-over when its third terminal 113 is separated from a mounting surface 124 (as in FIG. 13B). In some embodiments, the foot of the first terminal 111 can be dimensioned to be wider than the foot of the third terminal 113, such that even if the narrower third terminal 113 is separated from the mounting surface 124, the wider first terminal 111 provides a relatively stable orientation.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A multi-layer electrical device comprising multiple electrodes connected to respective terminals, at least two selected terminals configured to allow movement relative to each other to accommodate a change in separation distance of the respective electrodes resulting from a change in temperature, and to allow a solder to provide a connection therebetween when the multi-layer electrical device is soldered on a mounting surface.

2. The multi-layer electrical device of claim 1, further comprising a temperature-dependent layer implemented between each neighboring pair of electrodes.

3. The multi-layer electrical device of claim 2, wherein the temperature-dependent layer includes a material having a temperature-dependent electrical property, and wherein the temperature-dependent layer results in the change in separation distance of the respective neighboring pair of electrodes with the change in temperature.

4. The multi-layer electrical device of claim 3, wherein the material having the temperature-dependent electrical property is configured such that the separation distance of the respective neighboring pair of electrodes increases with an increase in temperature.

5. The multi-layer electrical device of claim 2, wherein the multiple electrodes include first, second and third electrodes connected to respective first, second and third terminals, such that a first temperature-dependent layer is between the first and second electrodes, and a second temperature-dependent layer is between the second and third electrodes, the first electrode being closest to the mounting surface when the multi-layer electrical device is mounted thereon.

6. The multi-layer electrical device of claim 5, wherein the at least two selected terminals include the first terminal and the third terminal.

7. The multi-layer electrical device of claim 6, wherein the first and third terminals are implemented on a first side of the multi-layer electrical device, and the second terminal is implemented on a second side of the multi-layer electrical device.

8. (canceled)

9. The multi-layer electrical device of claim 6, wherein each of the first and second temperature-dependent layers includes a positive temperature coefficient (PTC) material such that the respective temperature-dependent electrical property includes a resistance that increases with an increase in temperature.

10. (canceled)

11. (canceled)

12. (canceled)

13. (canceled)

14. (canceled)

15. The multi-layer electrical device of claim 6, wherein the first and third terminals are configured to include respective gap portions, such that the gap portion of the first terminal maintains a gap dimension with respect to the gap portion of the third terminal, the gap dimension being within a selected range during the relative movement.

16. The multi-layer electrical device of claim 15, wherein the selected range of the gap dimension is selected to allow a solder material to flow from one gap portion to the other gap portion during a soldering process to thereby allow the first and third terminals to become electrically connected.

17. The multi-layer electrical device of claim 15, wherein a change in dimension of each of the first and second temperature-dependent layers includes a thickness dimension change in a first direction that is normal to a plane of the first electrode.

18. The multi-layer electrical device of claim 17, wherein the gap portion of each of the first and third terminals includes an edge extending in a direction approximately parallel to the first direction.

19. The multi-layer electrical device of claim 18, wherein the edge of each of the first and second terminals defines one side of a respective tab having a width.

20. The multi-layer electrical device of claim 19, wherein the width of the tab of the first terminal is approximately the same as the width of the tab of the third terminal.

21. The multi-layer electrical device of claim 19, wherein the width of the tab of the first terminal is greater than the width of the tab of the third terminal.

22. The multi-layer electrical device of claim 17, wherein the first terminal includes a flat portion defining a plane that is approximately parallel with a plane of the first electrode, the flat portion having an inner edge, an outer edge, a thickness and a mounting side.

23. The multi-layer electrical device of claim 22, wherein the inner edge of the flat portion of the first terminal is connected to an edge of the first electrode by a connecting portion.

24. The multi-layer electrical device of claim 23, wherein the second terminal includes a flat portion defining a plane that is approximately parallel with a plane of the second electrode, the flat portion having an inner edge, an outer edge, a thickness and a mounting side.

25. The multi-layer electrical device of claim 24, wherein the outer edge of the flat portion of the second terminal is connected to an edge of the second electrode by a connecting portion.

26. The multi-layer electrical device of claim 23, wherein the flat portion of the first terminal defines a cutout along the outer edge, and the third terminal includes a terminal edge with a tab extending therefrom, the tab dimensioned to be at least partially within the cutout of the flat portion of the first terminal such that the cutout provides the gap portion for the first terminal and the tab provides the gap portion for the third terminal.

27. (canceled)

28. (canceled)

29. (canceled)

30. (canceled)
